(19) United States
(12) Patent Application Publication
(10) Pub. No.: US 2023/0284509 A1
(43) Pub. Date: Sep. 7, 2023

(54) DISPLAY DEVICE MANUFACTURING METHOD AND DISPLAY DEVICE

(71) Applicant: Japan Display Inc., Tokyo (JP)

(72) Inventors: Isao SUZUMURA, Tokyo (JP); Fumiya KIMURA, Tokyo (JP); Hiroshi OGAWA, Tokyo (JP)

(73) Assignee: Japan Display Inc., Tokyo (JP)

(21) Appl. No.: 18/175,549

(22) Filed: Feb. 28, 2023

(30) Foreign Application Priority Data
Mar. 2, 2022 (JP) 2022-031644

(51) Int. Cl. H10K 59/80; H10K 71/20

(52) U.S. Cl. CPC H10K 59/80524; H10K 59/871; H10K 71/231; H10K 2102/103

(57) ABSTRACT

According to one embodiment, a display device manufacturing method comprises forming a lower electrode including a first metal layer and a conductive oxide layer which covers the first metal layer and which has a thickness of 15 nm or more and 50 nm or less, forming a rib covering at least a part of the lower electrode and including a pixel aperture which exposes the conductive oxide layer, forming a second metal layer above the rib and the conductive oxide layer exposed through the pixel aperture, and patterning the second metal layer by etching including wet etching to form a partition on the rib.

### CROSS-REFERENCE TO RELATED APPLICATIONS

This application is based upon and claims the benefit of priority from Japanese Patent Application No. 2022-031644, filed Mar. 2, 2022, the entire contents of which are incorporated herein by reference.

### FIELD

Embodiments described herein relate generally to a display device manufacturing method and a display device.

### BACKGROUND

Recently, display devices with organic light-emitting diodes (OLEDs) applied thereto as display elements have been put into practical use. This display device comprises a lower electrode, an organic layer covering the lower electrode, and an upper electrode covering the organic layer.

When the display device is manufactured, various elements are formed by etching. In etching a certain element, when the other element is damaged, the reliability of the display device may be reduced.

### BRIEF DESCRIPTION OF THE DRAWINGS

FIG. 1 is a view showing a configuration example of a display device according to one of embodiments.

FIG. 2 is a view showing an example of layout of sub-pixels.

FIG. 3 is a schematic cross-sectional view showing the display device taken along line III-III in FIG. 2.

FIG. 4 is an enlarged cross-sectional view schematically showing a vicinity of a partition.

FIG. 5 is a flowchart showing an example of a method of manufacturing the display device.

FIG. 6 is a schematic cross-sectional view showing a part of a manufacturing process of the display device.

FIG. 7 is a schematic cross-sectional view showing a manufacturing process following FIG. 6.

FIG. 8 is a schematic cross-sectional view showing a manufacturing process following FIG. 7.

FIG. 9 is a schematic cross-sectional view showing a manufacturing process following FIG. 8.

FIG. 10 is a schematic cross-sectional view showing a manufacturing process following FIG. 9.

FIG. 11 is a schematic cross-sectional view showing a manufacturing process following FIG. 10.

FIG. 12 is a schematic cross-sectional view showing a manufacturing process following FIG. 11.

FIG. 13 is a schematic cross-sectional view showing a manufacturing process following FIG. 12.

FIG. 14 is a schematic cross-sectional view showing a manufacturing process following FIG. 13.

FIG. 15 is a schematic cross-sectional view showing a manufacturing process for forming a first display element.

FIG. 16 is a schematic cross-sectional view showing a manufacturing process following FIG. 15.

FIG. 17 is a schematic cross-sectional view showing a manufacturing process following FIG. 16.

FIG. 18 is a schematic cross-sectional view showing a manufacturing process following FIG. 17.

FIG. 19 is a schematic cross-sectional view showing a manufacturing process for forming a second display element.

FIG. 20 is a schematic cross-sectional view showing a manufacturing process for forming a third display element.

### DETAILED DESCRIPTION

In general, according to one embodiment, a display device manufacturing method comprises: forming a lower electrode including a first metal layer and a conductive oxide layer which covers the first metal layer and which has a thickness of 15 nm or more and 50 nm or less; forming a rib covering at least a part of the lower electrode and including a pixel aperture which exposes the conductive oxide layer; forming a second metal layer above the rib and the conductive oxide layer exposed through the pixel aperture; and patterning the second metal layer by etching including wet etching to form a partition on the rib.

In addition, according to another aspect of the embodiment, a display device comprises: a lower electrode including a first metal layer and a conductive oxide layer covering the first metal layer; a rib covering at least a part of the lower electrode and including a pixel aperture which exposes the conductive oxide layer; a partition arranged on the rib and including a second metal layer; an organic layer which is in contact with the conductive oxide layer through the pixel aperture; an upper electrode covering the organic layer; and a sealing layer arranged above the upper electrode. The conductive oxide layer has a thickness of 15 nm or more and 50 nm or less.

According to configurations of the manufacturing method and the display device, reliability of the display device can be improved.

An embodiment will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. To more clarify the explanations, the drawings may pictorially show width, thickness, shape and the like of each portion as compared with actual embodiments, but they are mere examples and do not restrict the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. Viewing various elements parallel to the third direction Z is referred to as planar view.

The display device of this embodiment is an organic electroluminescent display device comprising an organic light emitting diode (OLED) as a display element, and can be mounted on televisions, personal computers, vehicle-mounted devices, tablet terminals, smartphones, mobile phones, and the like.

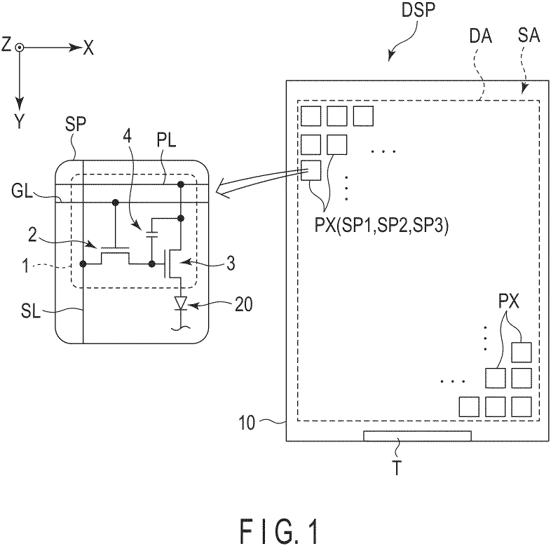

FIG. 1 is a plan view showing a configuration example of a display device DSP according to the embodiment. The display device DSP has a display area DA where images are displayed and a surrounding area SA around the display area DA, on an insulating substrate 10. The substrate 10 may be formed of glass or a flexible resin film.

In the embodiment, the shape of the substrate 10 in planar view is a rectangular shape. However, the shape of the substrate 10 in planar view is not limited to a rectangular shape, but may be any other shape such as a square, a circle or an ellipse.

The display area DA includes a plurality of pixels PX arrayed in a matrix in the first direction X and the second direction Y. Each of the pixels PX includes a plurality of sub-pixels SP. As an example, the pixel PX comprises a red sub-pixel SP1, a green sub-pixel SP2, and a blue sub-pixel SP3. The pixel PX may include sub-pixels SP of other colors such as a white color together with the sub-pixels SP1, SP2, and SP3 or instead of any of the sub-pixels SP1, SP2, and SP3.

The sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL, and the other is connected to a gate electrode of the drive transistor 3 and the capacitor 4. In the drive transistor 3, one of the source electrode and the drain electrode is connected to the power line PL and the capacitor 4, and the other is connected to the display element 20.

The configuration of the pixel circuit 1 is not limited to the example shown in the figure. For example, the pixel circuit 1 may comprise more thin-film transistors and more capacitors.

The display element 20 is an organic light-emitting diode (OLED) serving as a light emitting element. For example, the sub-pixel SP1 comprises a display element 20 that emits light of a red wavelength range, the sub-pixels SP2 comprises a display element 20 that emits light of a green wavelength range, and the sub-pixels SP3 comprises a display element 20 that emits light of a blue wavelength range.

A terminal portion T is provided in the surrounding area SA. The terminal portion T is connected to, for example, a substrate of an electronic device on which the display device DSP is mounted, via a flexible circuit board. A video signal and drive power for displaying images are input to the display device DSP via the terminal portion T.

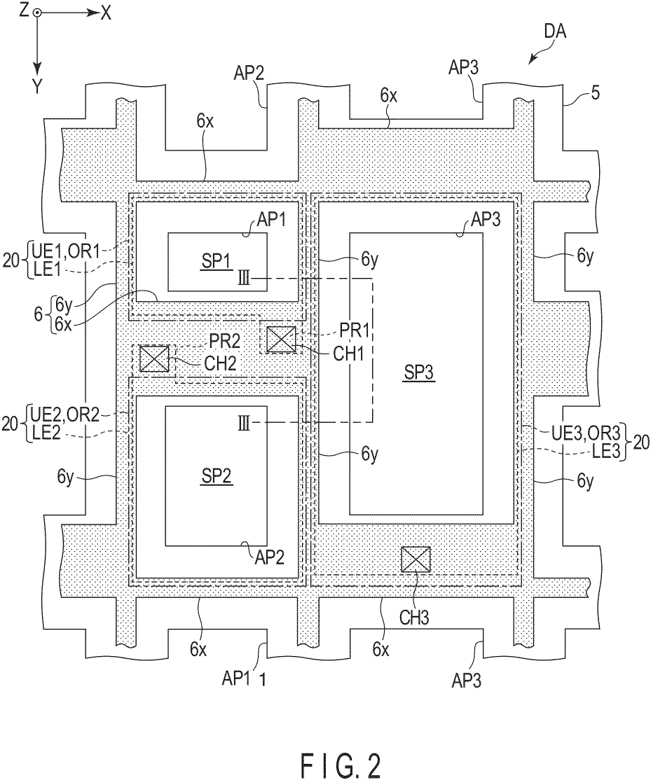

FIG. 2 is a view showing an example of a layout of the sub-pixels SP1, SP2, and SP3. In the example of FIG. 2, the sub-pixels SP1 and SP2 are arranged in the second direction Y. Furthermore, each of the sub-pixels SP1 and SP2 is arranged with the sub-pixel SP3 in the first direction X.

When the sub-pixels SP1, SP2, and SP3 are arranged in such a layout, a column in which the sub-pixels SP1 and SP2 are alternately arranged in the second direction Y and a column in which a plurality of sub-pixels SP3 are repeatedly arranged in the second direction Y are formed in the display area DA. These columns are alternately arranged in the first direction X.

The layout of the sub-pixels SP1, SP2, and SP3 is not limited to the example shown in FIG. 2. As another example, the sub-pixels SP1, SP2, and SP3 in each pixel PX may be arranged in order in the first direction X.

A rib 5 and a partition 6 are arranged in the display area DA. The rib 5 includes pixel apertures AP1, AP2, and AP3 in the sub-pixels SP1, SP2, and SP3, respectively. In the example shown in FIG. 2, the pixel aperture AP2 is larger than the pixel aperture AP1, and the pixel aperture AP3 is larger than the pixel aperture AP2.

The partition 6 is arranged at a boundary of adjacent sub-pixels SP and overlaps with the rib 5 in planar view. The partition 6 includes a plurality of first partitions 6x extending in the first direction X and a plurality of second partitions 6y extending in the second direction Y. The plurality of first partitions 6x are arranged between the pixel apertures AP1 and AP2 adjacent in the second direction Y and between two apertures AP3 adjacent in the second direction Y. The second partitions 6y are arranged between the pixel apertures AP1 and AP3 adjacent in the first direction X and between the pixel apertures AP2 and AP3 adjacent in the first direction X.

In the example shown in FIG. 2, the first partitions 6x and the second partitions 6y are connected to each other. Thus, the partition 6 has a grating pattern surrounding the pixel apertures AP1, AP2, and AP3 as a whole. The partition 6 is considered to include apertures at the sub-pixels SP1, SP2, and SP3, similarly to the rib 5.

The sub-pixel SP1 comprises a lower electrode LE1, an upper electrode UE1, and an organic layer OR1 each overlapping with the pixel aperture AP1. The sub-pixel SP2 comprises a lower electrode LE2, an upper electrode UE2, and an organic layer OR2 each overlapping with the pixel aperture AP2. The sub-pixel SP3 comprises a lower electrode LE3, an upper electrode UE3, and an organic layer OR3 each overlapping with the pixel aperture AP3. In the example shown in FIG. 2, outer shapes of the upper electrode UE1 and the organic layer OR1 correspond to each other, outer shapes of the upper electrode UE2 and the organic layer OR2 correspond to each other, and outer shapes of the upper electrode UE3 and the organic layer OR3 correspond to each other.

The lower electrode LE1, the upper electrode UE1, and the organic layer OR1 constitute the display element 20 of the sub-pixel SP1. The lower electrode LE2, the upper electrode UE2, and the organic layer OR 2 constitute the display element 20 of the sub-pixel SP2. The lower electrode LE3, the upper electrode UE3, and the organic layer OR3 constitute the display element 20 of the sub-pixel SP3.

The lower electrode LE1 is connected to the pixel circuit 1 of the sub-pixel SP1 (see FIG. 1) through a contact hole CH1. The lower electrode LE2 is connected to the pixel circuit 1 of the sub-pixel SP2 through a contact hole CH2. The lower electrode LE3 is connected to the pixel circuit 1 of the sub-pixel SP3 through a contact hole CH3.

In the example shown in FIG. 2, the contact holes CH1 and CH2 entirely overlap with the first partition 6x between the pixel apertures AP1 and AP2 adjacent to each other in the second direction Y. The contact hole CH3 entirely overlaps with the first partition 6x between two apertures AP3 adjacent to each other in the second direction Y. As another example, at least several parts of the contact holes CH1, CH2, and CH3 may not overlap with the first partition 6x.

In the example shown in FIG. 2, the lower electrodes LE1 and LE2 include protrusions PR1 and PR2, respectively. The protrusion PR1 protrudes from a main body of the lower electrode LE1 (portion overlapping with the pixel aperture AP1) toward the contact hole CH1. The protrusion PR2 protrudes from a main body of the lower electrode LE2 (portion overlapping with the pixel aperture AP2) toward the contact hole CH2. The contact holes CH1 and CH2 overlap with the protrusions PR1 and PR2, respectively.

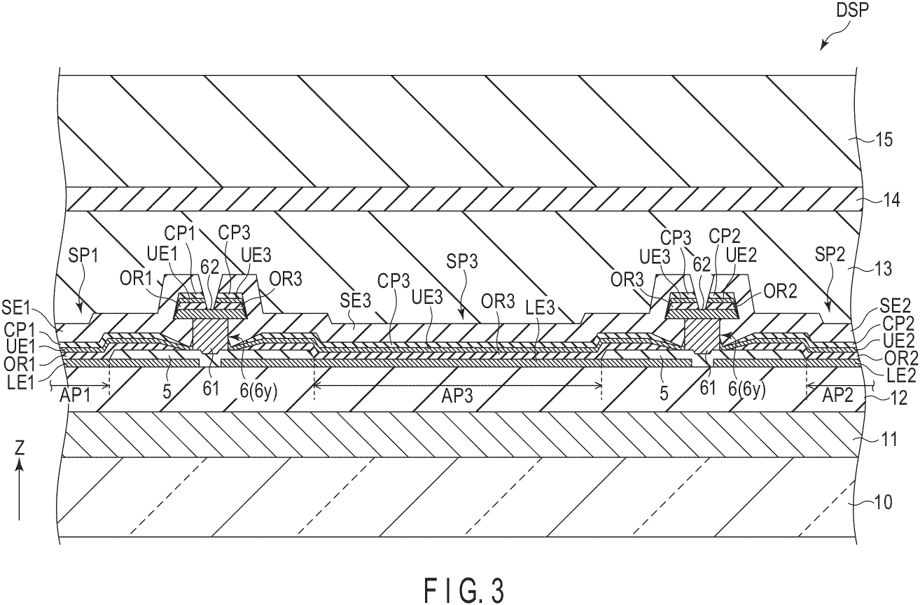

FIG. 3 is a schematic cross-sectional view showing the display device DSP taken along line III-III in FIG. 2. A circuit layer 11 is arranged on the substrate 10 described above. The circuit layer 11 includes various circuits and lines such as the pixel circuits 1, the scanning lines GL, the signal lines SL and the power lines PL shown in FIG. 1. The circuit layer 11 is covered with an organic insulating layer 12. The organic insulating layer 12 functions as a planarization film for planarizing uneven parts generated by the circuit layer 11. Although not shown in the cross section of FIG. 3, the contact holes CH1, CH2, and CH3 are provided in the organic insulating layer 12.

The lower electrodes LE1, LE2, and LE3 are arranged on the organic insulating layer 12. The rib 5 is arranged on the organic insulating layer 12 and the lower electrodes LE1, LE2, and LE3. End parts of the lower electrodes LE1, LE2, and LE3 are covered with the rib 5.

The partition 6 includes a lower portion 61 arranged on the rib 5 and an upper portion 62 arranged on the lower portion 61. The upper portion 62 has a width greater than the lower portion 61. As a result, both the end parts of the upper portion 62 protrude beyond the side surfaces of the lower portion 61 in FIG. 3. The shape of the partition 6 may also be referred to as an overhanging shape.

The organic layer OR1 covers the lower electrode LE1 through the pixel aperture AP1. The upper electrode UE1 covers the organic layer OR1 and is opposed to the lower electrode LE1. The organic layer OR2 covers the lower electrode LE2 through the pixel aperture AP2. The upper electrode UE2 covers the organic layer OR2 and is opposed to the lower electrode LE2. The organic layer OR3 covers the lower electrode LE3 through the pixel aperture AP3. The upper electrode UE3 covers the organic layer OR3 and is opposed to the lower electrode LE3.

In the example shown in FIG. 3, a cap layer CP1 is arranged on the organic layer OR1, a cap layer CP2 is arranged on the organic layer OR2, and a cap layer CP3 is arranged on the organic layer OR3. The cap layers CP1, CP2, and CP3 adjust optical properties of the light emitted from the organic layers OR1, OR2, and OR3, respectively.

A part of the organic layer OR1, the upper electrode UE1, and the cap layer CP1 is located on the upper portion 62. This part is separated from the other parts of the organic layer OR1, the upper electrode UE1, and the cap layer CP1. Similarly, a part of the organic layer OR2, the upper electrode UE2, and the cap layer CP2 is located on the upper portion 62, and this part is separated from the other parts of the organic layer OR2, the upper electrode UE2, and the cap layer CP2. Further, a part of the organic layer OR3, the upper electrode UE3, and the cap layer CP3 is located on the upper portion 62, and this part is separated from the other parts of the organic layer OR3, the upper electrode UE3, and the cap layer CP3.

Sealing layers SE1, SE2, and SE3 are arranged in the sub-pixels SP1, SP2, and SP3, respectively. The sealing layer SE1 continuously covers the cap layer CP1 and the partition 6. The sealing layer SE2 continuously covers the cap layer CP2 and the partition 6. The sealing layer SE3 continuously covers the cap layer CP3 and the partition 6.

In the example shown in FIG. 3, the organic layer OR1, the upper electrode UE1, the cap layer CP1, and the sealing layer SE1 on the partition 6 between the sub-pixels SP1 and SP3 are separated from the organic layer OR3, the upper electrode UE3, the cap layer CP3, and the sealing layer SE3 on this partition 6. In addition, the organic layer OR2, the upper electrode UE2, the cap layer CP2, and the sealing layer SE2 on the partition 6 between the sub-pixels SP2 and SP3 are separated from the organic layer OR3, the upper electrode UE3, the cap layer CP3, and the sealing layer SE3 on this partition 6.

The sealing layers SE1, SE2, and SE3 are covered with a resin layer 13. The resin layer 13 is covered with a sealing layer 14. Furthermore, the sealing layer 14 is covered with a resin layer 15.

The organic insulating layer 12 and the resin layers 13 and 15 are formed of an organic material.

The rib 5 and the sealing layers 14, SE1, SE2, and SE3 are formed of, for example, an inorganic material such as silicon nitride (SiNx). The rib 5 and the sealing layers 14, SE1, SE2, and SE3 may be formed as a single-layer body of any one of silicon oxide (SiOx), silicon oxynitride (SiON) and aluminum oxide (Al₂O₃). Alternatively, the rib 5 and the sealing layers 14, SE1, SE2, and SE3 may be formed as a stacked-layer body formed of combination of at least two of a silicon nitride layer, a silicon oxide layer, a silicon oxynitride layer, and an aluminum oxide layer.

The upper electrodes UE1, UE2, and UE3 are formed of, for example, a metallic material such as an alloy of magnesium and silver (MgAg). When potentials of the lower electrodes LE1, LE2, and LE3 are relatively higher than those of the upper electrodes UE1, UE2, and UE3, the lower electrodes LE1, LE2, and LE3 correspond to anodes, and the upper electrodes UE1, UE2, and UE3 correspond to cathodes. In addition, when the potentials of the upper electrodes UE1, UE2, and UE3 are relatively higher than those of the lower electrodes LE1, LE2, and LE3, the upper electrodes UE1, UE2, and UE3 correspond to anodes, and the lower electrodes LE1, LE2, and LE3 correspond to cathodes.

The organic layers OR1, OR2, and OR3 include a pair of functional layers and a light emitting layer interposed between these functional layers. As an example, each of the organic layers OR1, OR2, and OR3 has a structure in which a hole-injection layer, a hole-transport layer, an electron blocking layer, a light emitting layer, a hole blocking layer, an electron-transport layer, and an electron-injection layer are stacked in this order.

The cap layers CP1, CP2, and CP3 are formed of, for example, multilayer bodies of a plurality of transparent thin films. The multilayer body may include a thin film formed of an inorganic material and a thin film formed of an organic material, as the plurality of thin films. In addition, the plurality of thin films have refractive indices different from one another. The materials of the thin films constituting the multilayer body are different from the materials of the upper electrodes UE1, UE2, and UE3 and also different from the materials of the sealing layers SE1, SE2, and SE3. The cap layers CP1, CP2, and CP3 may be omitted.

A common voltage is supplied to the partition 6. This common voltage is supplied to each of the upper electrodes UE1, UE2, and UE3 that are in contact with the side surfaces of the lower portion 61. A pixel voltage is supplied to the lower electrodes LE1, LE2, and LE3 through the pixel circuits 1 included in the respective sub-pixels SP1, SP2, and SP3.

When a potential difference is formed between the lower electrode LE1 and the upper electrode UE1, the light emitting layer of the organic layer OR1 emits light of the red wavelength range. When a potential difference is formed between the lower electrode LE2 and the upper electrode UE2, the light emitting layer of the organic layer OR2 emits light of the green wavelength range. When a potential difference is formed between the lower electrode LE3 and the upper electrode UE3, the light emitting layer of the organic layer OR3 emits light of the blue wavelength range.

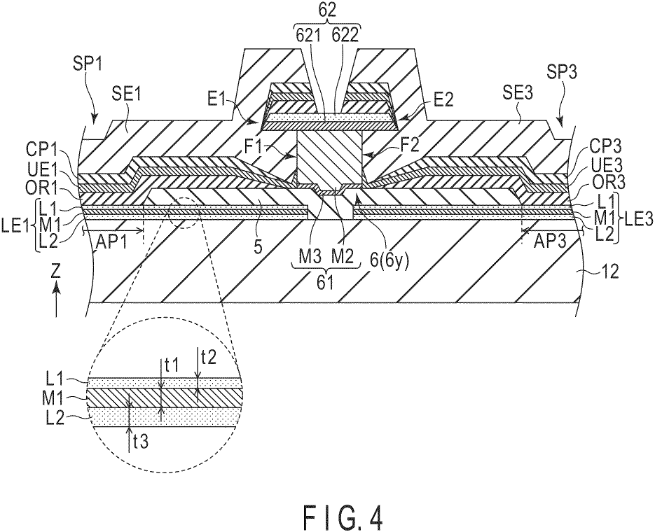

FIG. 4 is an expanded cross-sectional view schematically showing the partition 6 arranged on the boundary between the sub-pixels SP1 and SP3 and a vicinity of the partition 6. In this figure, the substrate 10, the circuit layer 11, the resin layer 13, the sealing layer 14, and the resin layer 15 are omitted.

In the example shown in FIG. 4, each of the lower electrodes LE1 and LE3 includes a first metal layer M1, a first conductive oxide layer L1 that is transparent and covers an upper surface of the first metal layer M1, and a second conductive oxide layer L2 that is transparent and covers a lower surface of the first metal layer M1. The organic layer OR1 is in contact with the first conductive oxide layer L1 of the lower electrode LE1 through the pixel aperture AP1. The organic layer OR3 is in contact with the first conductive oxide layer L1 of the lower electrode LE3 through the pixel aperture AP3. Although not shown in the cross-section of FIG. 4, the lower electrode LE2 also includes the first metal layer M1, the first conductive oxide layer L1, and the second conductive oxide layer L2, and the organic layer OR2 is in contact with the first conductive oxide layer L1 of the lower electrode LE2 through the pixel aperture AP2.

The first metal layer M1 is formed of, for example, silver (Ag) and reflects the light emitted from the organic layers OR1, OR2, and OR3 in the upward direction. The first conductive oxide layer L1 and the second conductive oxide layer L2 are formed of, for example, indium tin oxide (ITO), suppressing oxidation of the first metal layer M1. Furthermore, the first conductive oxide layer L1 improves the work function of the lower electrodes LE1, LE2, and LE3, and the second conductive oxide layer L2 improves the adhesion of the lower electrodes LE1, LE2, and LE3 to the organic insulating layer 12.

The first metal layer M1 has thickness t1, the first conductive oxide layer L1 has thickness t2, and the second conductive oxide layer L2 has thickness t3. The thicknesses t1, t2, and t3 correspond to, for example, average thicknesses of the first metal layer M1, the first conductive oxide layer L1, and the second conductive oxide layer L2, respectively.

In the embodiment, the thickness t2 is smaller than the thicknesses t1 and t3. However, the thickness t2 may be larger than the thickness t3. As an example, the thickness t1 is approximately 100 nm, and the thickness t3 is 10 nm or more and 100 nm or less. In addition, the thickness t2 is 15 nm or more and 50 nm or less and, preferably, 20 nm or more and 40 nm or less.

The lower portion 61 of the partition 6 has a side surface F1 and a side surface F2. The upper portion 62 of the partition 6 includes an end portion E1 protruding from the side surface F1 and an end portion E2 protruding from the side surface F2. The upper electrodes UE1 and UE3 are in contact with the side surfaces F1 and F2, respectively.

In the example shown in FIG. 4, the lower portion 61 includes a second metal layer M2 and a third metal layer M3. The third metal layer M3 is arranged on the rib 5. The second metal layer M2 is arranged on the third metal layer M3. In addition, the upper portion 62 includes a first thin film 621 arranged on the second metal layer M2 and a second thin film 622 arranged on the first thin film 621.

For example, the second metal layer M2 is formed of aluminum (Al) so as to be thicker than the third metal layer M3. The third metal layer M3 is formed of, for example, molybdenum (Mo). The first thin film 621 is formed of, for example, titanium (Ti). The second thin film 622 is formed of, for example, ITO.

The materials of the first metal layer M1 and the second metal layer M2 are not limited to silver and aluminum. For example, each of the first metal layer M1 and the second metal layer M2 can be formed of the metal material selected from aluminum, aluminum alloy, silver, silver alloy and the like.

In addition, the material of the first conductive oxide layer L1, the second conductive oxide layer L2, and the second thin film 622 is not limited to ITO. Each of the first conductive oxide layer L1, the second conductive oxide layer L2, and the second thin film 622 can be formed of a transparent conductive oxide (metal oxide) selected from ITO, indium zinc oxide (IZO), indium gallium zinc oxide (IGZO), and the like. The upper portion 62 does not need to have the multilayer structure of the first thin film 621 and the second thin film 622, but may have a single-layer structure of titanium, silicon oxide, or the like.

In the example shown in FIG. 4, the end portions of the lower electrodes LE1 and LE3 are located under the lower portion 61. In other words, the end portions of the lower electrodes LE1 and LE3 overlap with the lower portion 61 in planar view. As shown in FIG. 3, the end portion of the lower electrode LE2 is also located under the lower portion 61.

Next, a method of manufacturing the display device DSP will be described.

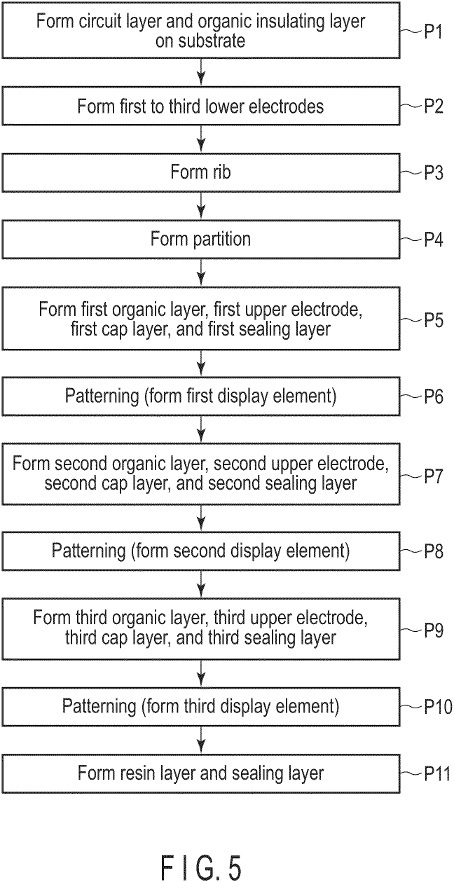

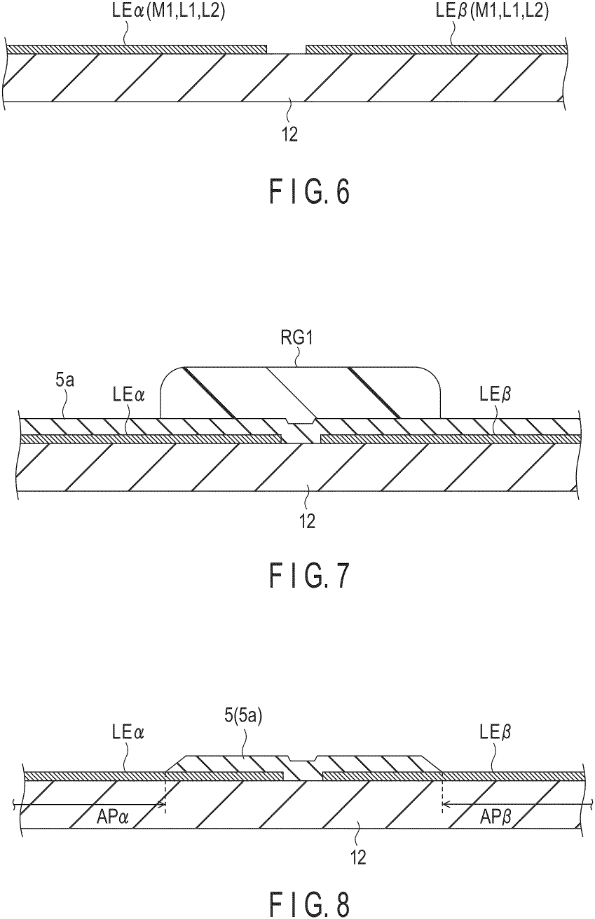

FIG. 5 is a flowchart showing an example of a method of manufacturing the display device DSP. FIG. 6 to FIG. 20 are schematic cross-sectional views showing parts of the method of manufacturing the display device DSP.

In the embodiment, the display elements 20 of the sub-pixels SP1, SP2, and SP3 are formed by separate processes. Although the order in which the display elements 20 of the sub-pixels SP1, SP2, and SP3 are formed is not particularly limited, the sub-pixel in which the display element 20 is formed first is referred to as a first sub-pixel SPα, the sub-pixel in which the display element 20 is formed second is referred to as a second sub-pixel SPβ, and the sub-pixel in which the display element 20 is formed third is referred to as a third sub-pixel SPγ, for convenience of description.

In addition, the lower electrode, the organic layer, the upper electrode, the cap layer, the sealing layer, the pixel aperture and the display element of the first sub-pixel SPα are referred to as a first lower electrode LEα, a first organic layer ORα, a first upper electrode UEα, a first cap layer CPα, a first sealing layer SEα, a first pixel aperture APα and a first display element 20α. The lower electrode, the organic layer, the upper electrode, the cap layer, the sealing layer, the pixel aperture, and the display element of the second sub-pixel SPβ are referred to as a second lower electrode LEβ, a second organic layer ORβ, a second upper electrode UEβ, a second cap layer CPβ, a second sealing layer SEβ, a second pixel aperture APβ, and a second display element 20β. The lower electrode, the organic layer, the upper electrode, the cap layer, the pixel aperture, and the display element of the third sub-pixel SPγ are referred to as a third lower electrode LEγ, a third organic layer ORγ, a third upper electrode UEγ, a third cap layer CPγ, a third sealing layer SEγ, a third pixel aperture APγ, and a third display element 20γ.

In manufacturing the display device DSP, the circuit layer 11 and the organic insulating layer 12 are first formed on the substrate 10 (process P1 in FIG. 5).

After the process P1, the first lower electrode LEα and the second lower electrode LEβ are formed on the organic insulating layer 12 (above the substrate 10), as shown in FIG. 6 (process P2 in FIG. 5). At this time, the third lower electrode LEγ is also formed. The lower electrodes LEα, LEβ, and LEγ include the first metal layer M1, the first conductive oxide layer L1, and the second conductive oxide layer L2 described above.

After the process P2, the rib 5 is formed (process P3 in FIG. 5). More specifically, as shown in FIG. 7, an insulating layer 5a which is the base of the rib 5 is first formed, and a resist RG1 corresponding to the shape of the partition 6 is formed on the insulating layer 5a. The insulating layer 5a is formed of, for example, an inorganic material such as silicon nitride and covers the first lower electrode LEα, the second lower electrode LEβ, and the third lower electrode LEγ.

Next, etching is executed using the resist RG1 as a mask, and a portion of the insulating layer 5a, which is exposed from the resist RG1, is thereby removed. Thus, as shown in FIG. 8, the rib 5 including the first pixel aperture APα, the second pixel aperture APβ, and the third pixel aperture APγ is formed. After the formation of the pixel apertures APα, APβ, and APγ, the resist RG1 is removed.

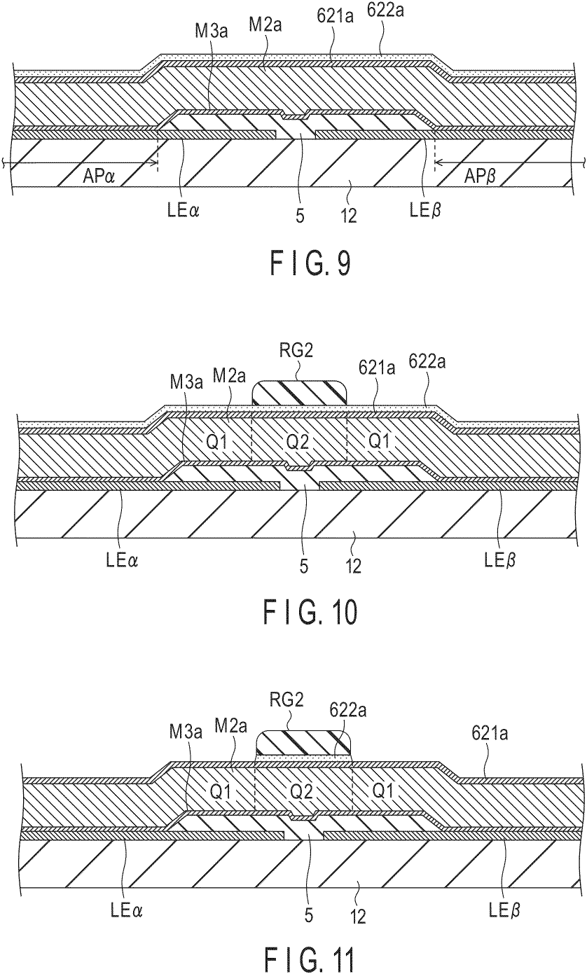

After the process P3, the partition 6 is formed (process P4 in FIG. 5). More specifically, as shown in FIG. 9, first, a third metal layer M3a covering the lower electrodes LEα, LEβ, and LEγ and the rib 5 exposed through the pixel apertures APα, APβ, and APγ is formed, a second metal layer M2a is formed on the third metal layer M3a, a first thin film 621a is formed on the second metal layer M2a, and a second thin film 622a is formed on the first thin film 621a. All the second metal layer M2a, the third metal layer M3a, the first thin film 621a, and the second thin film 622a are located above the rib 5 and the first conductive oxide layer L1 (see FIG. 4) exposed through the pixel apertures APα, APβ, and APγ.

Next, as shown in FIG. 10, a resist RG2 corresponding to the shape of the partition 6 is formed on the second thin film 622a. In the following descriptions, a portion of the second metal layer M2a exposed from the resist RG2 is referred to as a first portion Q1, and a portion located below the resist RG2 is referred to as a second portion Q2.

After the formation of the resist RG2, a portion of the second thin film 622a exposed from the resist RG2 is removed by wet etching using the resist RG2 as a mask as shown in FIG. 11.

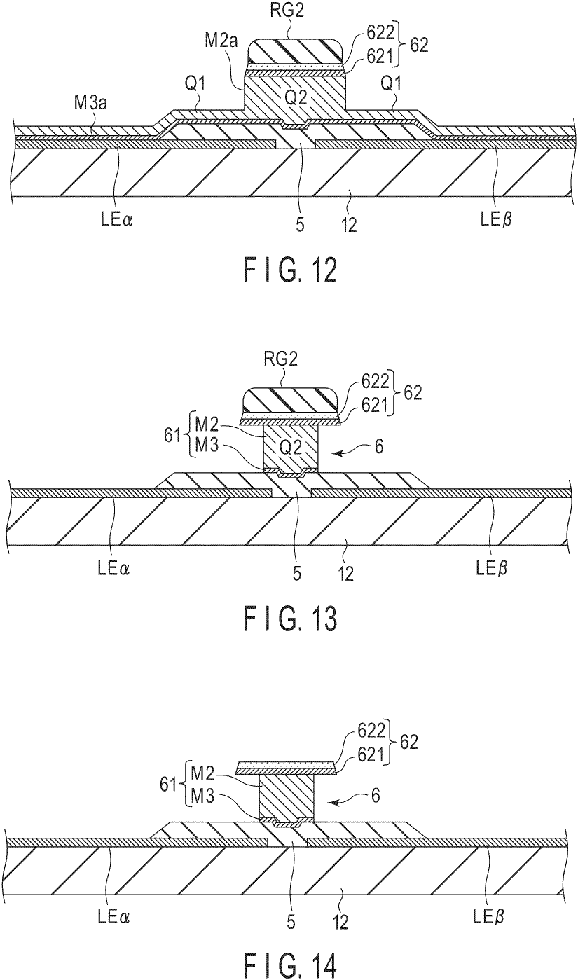

Anisotropic dry etching is then executed to remove the portion of the first thin film 621a which is exposed from the resist RG2, as shown in FIG. 12. The upper portion 62 including the first thin film 621 and the second thin film 622 is thereby formed. In the dry etching, the thickness of the first portion Q1 of the second metal layer M2a is also reduced.

Isotropic wet etching is then performed to remove the first portion Q1 and the third metal layer M3a located below the portion, as shown in FIG. 13. In the wet etching, since the side surfaces of the second portion Q2 are also eroded, the width of the second portion Q2 is further reduced than the width of the upper portion 62. As a result, the lower portion 61 including the second metal layer M2 and the third metal layer M3 is formed. After the formation of the lower portion 61, the resist RG2 is removed as shown in FIG. 14.

For the wet etching, for example, an etchant containing 60% or more by weight and 70% or less by weight of phosphoric acid, 8% or more by weight and 10% or less by weight of nitric acid, 2% or more by weight and 5% or less by weight of acetic acid, and water is used. The etchant may contain additives such as ammonium fluoride (NH₄F). Such etchant will erode aluminum, aluminum alloys, silver, and silver alloys that may be selected as materials for the first metal layer M1 and the second metal layer M2. Weak alkaline etchant or the like may be used as the etchant.

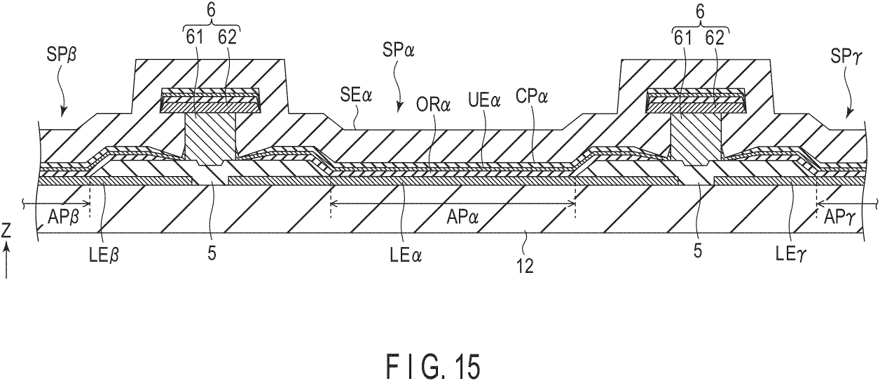

After the process P4, the first organic layer ORα contacting the first lower electrode LEα through the first pixel aperture APα, the first upper electrode UEα covering the first organic layer ORα, the first cap layer CPα covering the first upper electrode UEα, and the first sealing layer SEα covering the first cap layer CPα are formed in this order by vapor deposition (process P5 in FIG. 5) as shown in FIG. 15. The first organic layer ORα, the first upper electrode UEα, the first cap layer CPα, and the first sealing layer SEα are formed at least for the entire display area DA, and are located not only in the first sub-pixel SPα but also in the second sub-pixel SPβ and the third sub-pixel SPγ.

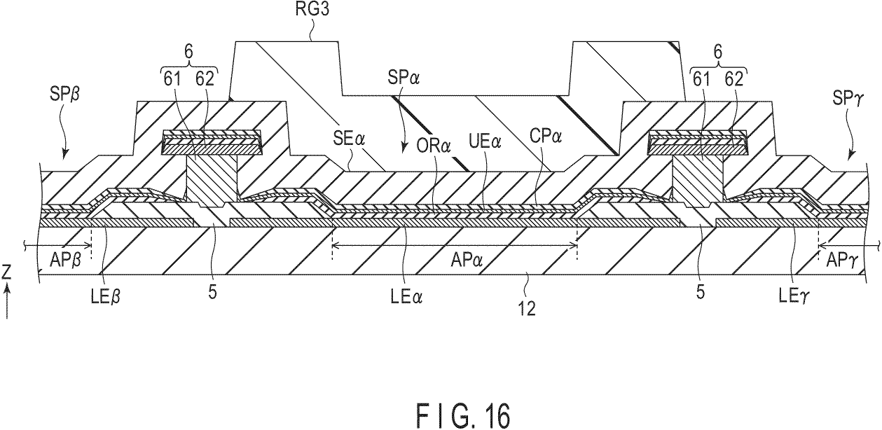

After the process P5, the first organic layer ORα, the first upper electrode UEα, the first cap layer CPα and the first sealing layer SEα are patterned (process P6 in FIG. 5). More specifically, a resist RG3 is first arranged on the first sealing layer SEα as shown in FIG. 16. The resist RG3 is located right above the first lower electrode LEα. The resist RG3 is also located right above a portion of the partition 6 between the sub-pixels SPα and SPβ that is closer to the first sub-pixel SPα, and a portion of the partition 6 between the sub-pixels SPα and SPγ that is closer to the first sub-pixel SPα.

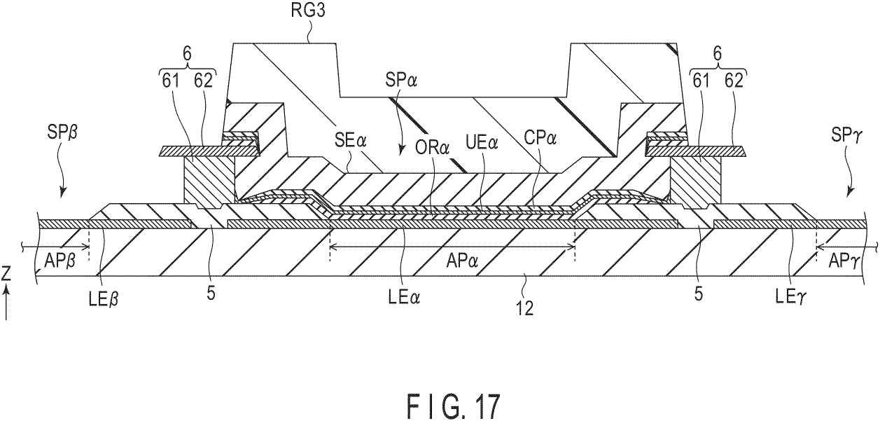

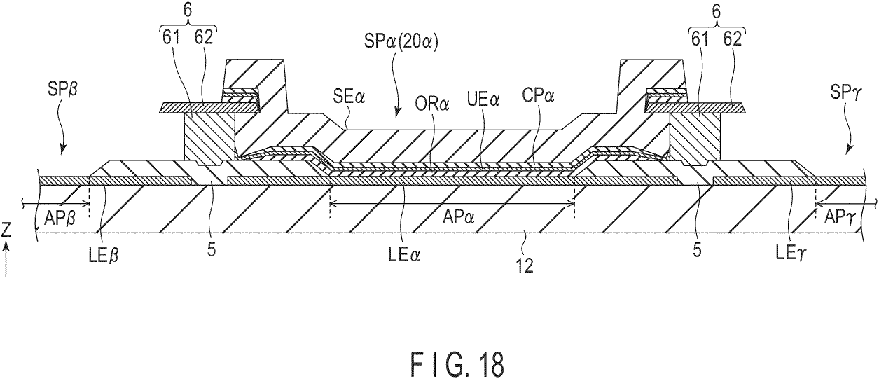

Next, as shown in FIG. 17, the portions of the first organic layer ORα, the first upper electrode UEα, the first cap layer CPα, and the first sealing layer SEα which are exposed from the resist RG3 are removed by etching using the resist RG3 as a mask. After that, as shown in FIG. 18, the resist RG3 is removed, and the first display element 20α including the first lower electrode LEα, the first organic layer ORα, the first upper electrode UEα, the first cap layer CPα, and the first sealing layer SEα is completed.

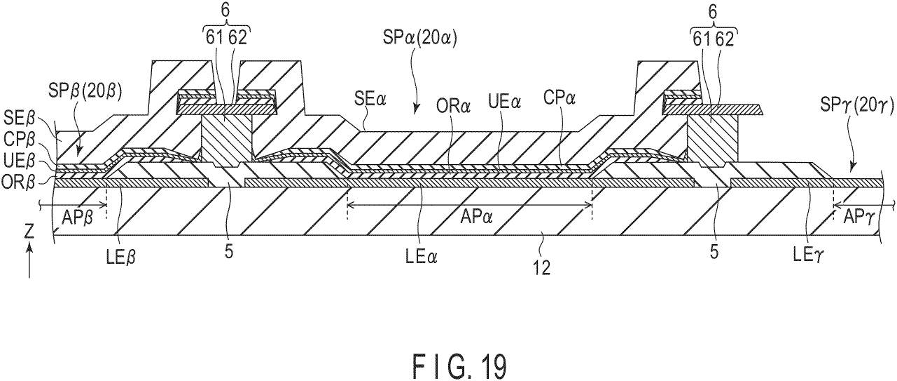

After the process P6, the second organic layer ORβ contacting the second lower electrode LEβ through the second pixel aperture APβ, the second upper electrode UEβ covering the second organic layer ORβ, the second cap layer CPβ covering the second upper electrode UEβ, and the second sealing layer SEβ covering the second cap layer CPβ are formed in this order by vapor deposition (process P7 in FIG. 5). Furthermore, as shown in FIG. 19, the second display element 20β including the second lower electrode LEβ, the second organic layer ORβ, the second upper electrode UEβ, the second cap layer CPβ, and the second sealing layer SEβ is formed in the second sub-pixel SPβ by the same patterning as that in the process P6 (process P8 in FIG. 5).

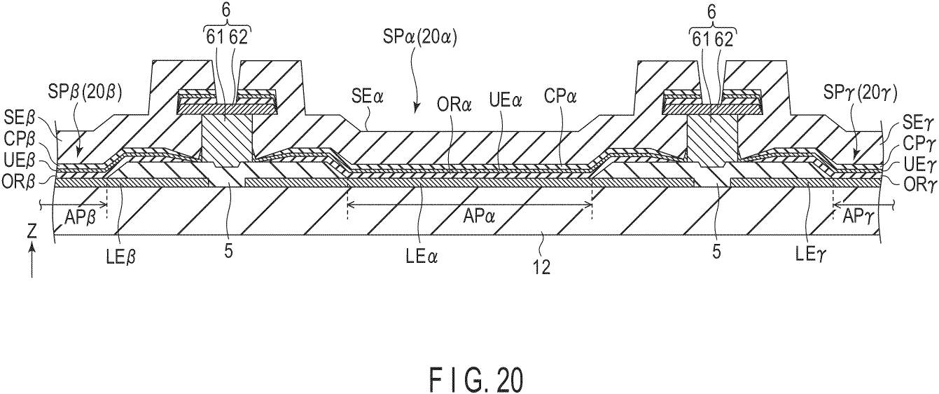

After the process P8, the third organic layer ORγ contacting the third lower electrode LEγ through the third pixel aperture APγ, the third upper electrode UEγ covering the third organic layer ORγ, the third cap layer CPγ covering the third upper electrode UEγ, and the third sealing layer SEγ covering the third cap layer CPγ are formed in this order by vapor deposition (process P9 in FIG. 5). Furthermore, as shown in FIG. 20, the third display element 20γ including the third bottom electrode LEγ, the third organic layer ORγ, the third upper electrode UEγ, the third cap layer CPγ, and the third encapsulating layer SEγ is formed in the third sub-pixel SPγ by the same patterning as that in the process P6 (process P10 in FIG. 5).

After the display elements 20α, 20β, and 20γ are thus formed, the resin layer 13, the sealing layer 14, and the resin layer 15 shown in FIG. 3 are formed in this order to complete the display device DSP (process P11 in FIG. 5).

In the method of manufacturing the display device DSP described above, wet etching is used for patterning the lower portion 61 of the partition 6 (process in FIG. 13). In the wet etching, the lower electrodes LEα, LEβ, and LEγ are exposed to the etchant through the pixel apertures APα, APβ, and APγ. If the first conductive oxide layer L1 of the lower electrodes LEα, LEβ, and LEγ has a defective part such as a minute pinhole, the etchant can reach the first metal layer M1 through this defective part. In this case, at least a part of the first metal layer M1 may disappear.

In contrast, if the first conductive oxide layer L1 is formed to be thicker, the occurrence of defective part where the etchant reaches the first metal layer M1 can be suppressed. The present inventors conducted experiments to verify this effect. In this experiment, seven samples in which an ITO lower conductive oxide layer, a silver metal layer, and an ITO upper conductive oxide layer were formed on the substrate in this order were prepared. In each sample, the thickness of the metal layer is 100 nm, and the thickness of the lower conductive oxide layer is 7 nm. In each sample, the thickness of the upper conductive oxide layer was different, i.e., 7 nm, 14 nm, 21 nm, 28 nm, 35 nm, 42 nm, and 49 nm.

Wet etching was executed on these samples at 40° C. for 2 minutes. In this wet etching, an etchant containing 60% or more by weight and 70% or less by weight of phosphoric acid, 8% or more by weight and 10% or less by weight of nitric acid, and 2% or more by weight and 5% or less by weight of acetic acid was used.

As a result, in the sample in which the thickness of the upper conductive oxide layer was 7 nm, the metallic layer entirely disappeared in approximately 15 seconds. In addition, in the sample in which the thickness of the upper conductive oxide layer was 14 nm, the metallic layer did not disappear, but its thickness was entirely reduced.

In the samples in which the thickness of the upper conductive oxide layer was 21 nm, 28 nm, 35 nm, 42 nm, and 49 nm, entire loss of the metal layer or reduction in thickness did not occur. In these samples, however, partial damage to the metal layer was observed, which is thought to be caused by the defective parts such as pinholes in the upper conductive oxide layer. It was confirmed that this damage was reduced as the thickness of the upper conductive oxide layer was larger.

Based on the above experiments, the thickness of the first conductive oxide layer L1 (upper conductive oxide layer) is desirably a value greater than 14 nm, for example, 15 nm or more. The effect is more desirable if the thickness of the first conductive oxide layer L1 is 20 nm or more.

The lower electrode and the upper electrodes which constitute the display element 20 form a microcavity structure that the light emitted by the organic layer is subjected to multiple reflections. In realizing this microcavity structure, the optical path length between the lower electrode and the upper electrode needs to be set to an appropriate value according to the wavelength of the light emitted from the organic layer. In general, conductive oxides such as ITO are formed by sputtering and are inferior to organic layers formed by vapor deposition in terms of uniformity in film thickness. For this reason, if the first conductive oxide layer L1 is formed to be too thick, it is difficult to obtain a uniform microcavity structure. Furthermore, since ITO tends to absorb light of shorter wavelengths, for example, the efficiency of blue sub-pixels, for example, may be degraded if the first conductive oxide layer L1 is formed of ITO to be thick.

Considering the above, the thickness of the first conductive oxide layer L1 is desirably 50 nm or less. The effect is more desirable if the thickness of the first conductive oxide layer L1 is 40 nm or less.

By thus adjusting the thickness of the first conductive oxide layer L1 to be 15 nm or more and 50 nm or less, preferably 20 nm or more and 40 nm or less, display failure caused by damage to the first metal layer M1 and non-uniformity in the microcavity structure can be suppressed, and the reliability of the display device DSP can be enhanced.

In addition, if the first conductive oxide layer L1 is made thicker, a stepped portion caused by the lower electrode is likely to occur on the upper surface of the rib 5. If a thin upper electrode is formed on this stepped portion, the upper electrode may be interrupted. In contrast, in the examples shown in FIG. 3 and FIG. 4, the end portions of the lower electrodes LE1, LE2, and LE3 are located under the lower portion 61 of the partition 6. In this case, since the stepped portions on the upper surface of the rib 5 caused by the lower electrodes LE1, LE2, and LE3 are covered with the lower portion 61, the interruption of the upper electrodes UE1, UE2, and UE3 can be suppressed and, as a result, the reliability of the display device DSP can be further improved.

All of the display devices and manufacturing methods that can be implemented by a person of ordinary skill in the art through arbitrary design changes to the display devices and manufacturing methods described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, the above embodiments with addition, deletion, and/or designed change of their structural elements by a person having ordinary skill in the art, or the above embodiments with addition, omission, and/or condition change of their processes by a person having ordinary skill in the art are encompassed by the scope of the present inventions without departing the spirit of the inventions.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device manufacturing method comprising:
forming a lower electrode including a first metal layer and a conductive oxide layer which covers the first metal layer and which has a thickness of 15 nm or more and 50 nm or less;
forming a rib covering at least a part of the lower electrode and including a pixel aperture which exposes the conductive oxide layer;
forming a second metal layer above the rib and the conductive oxide layer exposed through the pixel aperture; and
patterning the second metal layer by etching including wet etching to form a partition on the rib.

2. The method of claim 1, wherein
a thickness of the conductive oxide layer is 20 nm or more and 40 nm or less.

3. The method of claim 1, wherein
the first metal layer and the second metal layer are formed of one of aluminum, aluminum alloy, silver, and silver alloy.

4. The method of claim 1, wherein
the conductive oxide layer is formed of ITO or IZO.

5. The method of claim 1, wherein
the rib is formed of an inorganic material.

6. The method of claim 5, wherein
the rib is formed of one of a silicon nitride, a silicon oxide, and a silicon oxynitride.

7. The method of claim 1, wherein
an etchant used for the wet etching erodes the material of the first metal layer and the material of the second metal layer.

8. The method of claim 7, wherein
the etchant contains phosphoric acid, nitric acid, and acetic acid.

9. The method of claim 8, wherein
the etchant contains 60% or more by weight and 70% or less by weight of phosphoric acid, 8% or more by weight and 10% or less by weight of nitric acid, and 2% or more by weight and 5% or less by weight of acetic acid.

10. The method of claim 1, wherein
the forming the partition comprises:
arranging a resist above the second metal layer;
reducing a thickness of a first portion of the second metal layer, which is exposed from the resist, by dry etching; and
removing the first portion whose thickness is reduced and reducing a width of a second portion of the second metal layer, which is located under the resist, by the wet etching.

11. The method of claim 1, further comprising:
after forming the partition, forming an organic layer which is in contact with the lower electrode through the pixel aperture;
forming an upper electrode covering the organic layer; and
patterning the organic layer and the upper electrode to form a display element including the lower electrode, the organic layer, and the upper electrode.

12. A display device comprising:
a lower electrode including a first metal layer and a conductive oxide layer covering the first metal layer;
a rib covering at least a part of the lower electrode and including a pixel aperture which exposes the conductive oxide layer;
a partition arranged on the rib and including a second metal layer;
an organic layer which is in contact with the conductive oxide layer through the pixel aperture;
an upper electrode covering the organic layer; and
a sealing layer arranged above the upper electrode, wherein
the conductive oxide layer has a thickness of 15 nm or more and 50 nm or less.

13. The display device of claim 12, wherein
a thickness of the conductive oxide layer is 20 nm or more and 40 nm or less.

14. The display device of claim 12, wherein
the partition includes a lower portion including the second metal layer and an upper portion protruding from a side surface of the lower portion.

15. The display device of claim 14, wherein
the upper electrode is in contact with the side surface of the lower portion.

16. The display device of claim 12, further comprising:
a cap layer covering the upper electrode.
